(19) United States
(12) Patent Application Publication
(10) Pub. No.: US 2007/0158796 A1
(43) Pub. Date: Jul. 12, 2007

(54) Semiconductor package

(75) Inventor: Andrew N. Sawle, East Grinstead (GB)

Correspondence Address: OSTROLENK FABER GERB & SOFFEN, 1180 AVENUE OF THE AMERICAS, NEW YORK, NY, 100368403, US

(73) Assignee: International Rectifier Corporation

(21) Appl. No.: 11/636,210

(22) Filed: Dec. 8, 2006

Related U.S. Application Data
(60) Provisional application No. 60/748,890, filed on Dec. 9, 2005.

(51) Int. Cl. H01L 23/495

(52) U.S. Cl. 257/675

(57) ABSTRACT

A semiconductor package that includes a semiconductor device that is integrated with a silicon substrate.

### RELATED APPLICATION

This application is based on and claims priority to the U.S. Provisional Application Ser. No. 60/748,890, filed on Dec. 9, 2005, entitled Redistribution of Small Die Pads Using a Silicon Substrate, to which a claim of priority is hereby made and the disclosure of which is incorporated by reference.

### BACKGROUND OF THE INVENTION

The present invention relates to semiconductor packages and methods of fabricating semiconductor packages.

As demand for improved performance and reduction in the cost of semiconductor devices such as power semiconductor devices increases, the size of semiconductor devices decreases while the performance thereof increases. Specifically, it is anticipated that to reduce the cost of manufacturing more die must be fabricated out of a single wafer, while each die must provide better characteristics, such as more current carrying capability per unit area. Consequently, it is expected that as the die size decreases the electrodes thereof that make external connection via, for example, a solder body will also decrease in size while the current passed therethrough will increase.

It is believed that the reduction in the size of the electrodes combined with an increase in the current load passing through the electrode and its solder connection, particularly in the presence of high switching frequencies, may result in a higher than desirable failure rate in the solder connection due, for example, to electromigration or the like phenomenon.

Furthermore, it may become difficult for the end users of semiconductor die to adapt to connecting semiconductor die to conductive pads or the like of circuit boards if the electrodes are made small.

### SUMMARY OF THE INVENTION

It is an object of the present invention to provide a semiconductor package configuration which allows the use of smaller die with a larger area for external connection.

A semiconductor package according to the present invention includes a silicon substrate having a total area, a semiconductor device having a total area smaller than the total area of the substrate and at least one active electrode, a conductive pad electrically and mechanically connected to the at least one active electrode and disposed on the silicon substrate, wherein the conductive pad includes an area for external connection that is larger than the area of the at least one active electrode.

In one embodiment of the present invention, the conductive pad is disposed between the silicon substrate and the semiconductor die, and may further include an interconnect serving as a lead formed with an electrically conductive mass that includes conductive particles dispersed within a solder matrix, or a conductive ball formed on the area for external connection.

In another embodiment according to the present invention, the semiconductor device is disposed within a recess in the substrate and the conductive pad is disposed on a surface of the substrate that is parallel to a surface on which the at least one electrode is disposed. The conductive pad may be generally coplanar with the at least one electrode.

In another embodiment, the package may include more than one semiconductor device and even passive components to form an integrated circuit using only one substrate.

As further enhancements a heat spreader may be thermally coupled to the substrate, a passivation body may be disposed on the substrate to define the appropriate areas for the interconnects and the electrodes of the semiconductor device, and a filler mass may be disposed between the semiconductor device and the substrate.

Other features and advantages of the present invention will become apparent from the following description of the invention which refers to the accompanying drawings.

### BRIEF DESCRIPTION OF THE DRAWING(S)

FIG. 1 illustrates a side view of a semiconductor package according to the first embodiment of the present invention.

FIG. 2 illustrates a package according to the first embodiment mounted on a circuit board.

FIG. 3 illustrates a package according to the first embodiment as mounted on a circuit board and further including a heat spreader/electrical connector.

FIG. 4 illustrates a side view of a semiconductor package according to the second embodiment mounted on a circuit board.

FIG. 5 illustrates a semiconductor package according to the second embodiment that includes a filler body around the semiconductor device mounted on a circuit board.

FIG. 6 illustrates a side view of a semiconductor package according to the third embodiment.

FIG. 7 illustrates a top plan view of a semiconductor package according to the fourth embodiment of the present invention.

FIG. 8 illustrates a cross-sectional view of a package according to the fourth embodiment along line 8-8 viewed in the direction of the arrows.

FIGS. 9A-9D illustrate selected steps in the fabrication of a device according to the present invention.

FIG. 10 illustrates a top plan view of a silicon substrate that includes more than two conductive pads.

### DETAILED DESCRIPTION OF EMBODIMENTS OF THE INVENTION

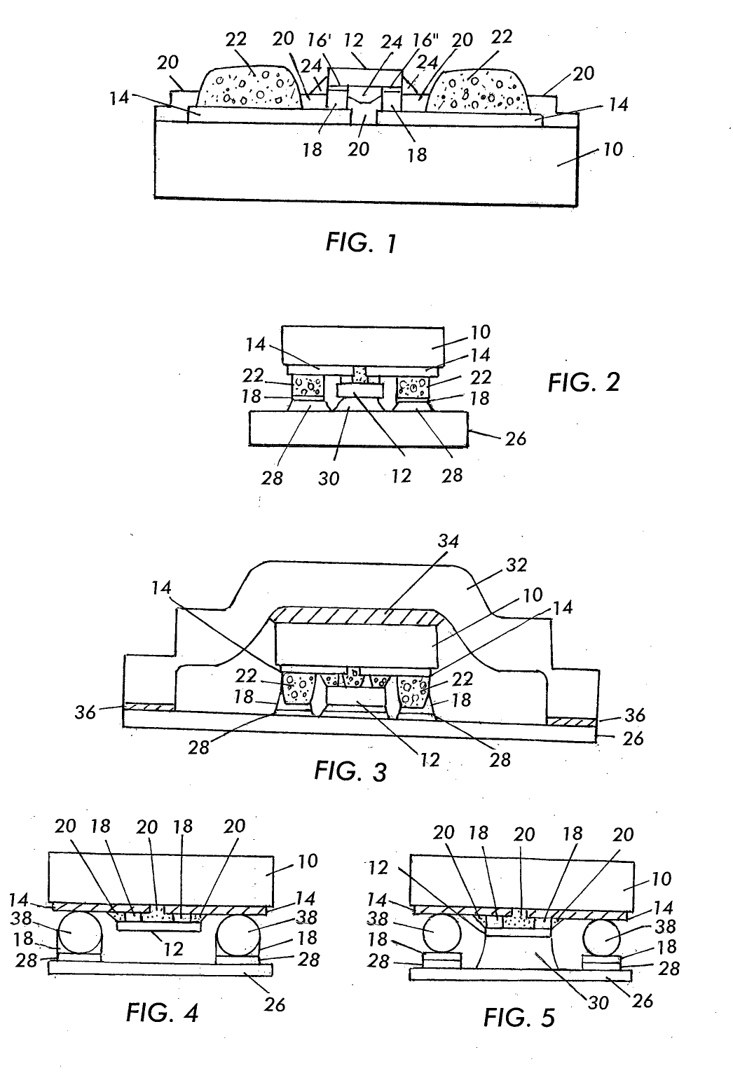

Referring to FIG. 1, a semiconductor package according to the first embodiment of the present invention includes a silicon substrate 10 and a semiconductor device 12 assembled onto silicon substrate 10. Specifically, silicon substrate 10 includes conductive pads 14 disposed on one surface thereof each being electrically and mechanically coupled to a respective active electrode 16′, 16″ of semiconductor device 12 through a conductive adhesive (e.g. solder, or a conductive polymer such as silver loaded epoxy) body 18. Note semiconductor device 12 may be a power semiconductor device such as a power MOSFET, or an IGBT, or a III-nitride based power device such as a high electron mobility transistor. An active electrode such as electrode 16′ (or electrode 16″) of semiconductor device 12 may be a power electrode such as the source electrode or the drain electrode, or the control electrode, e.g. the gate electrode.

A package according to the preferred embodiment may further include a passivation body 20 which may exhibit solder-resist characteristics such as a polymer-based solder resist, and an interconnect body 22 electrically and mechanically coupled to each conductive pad 14 to serve as an external connector (or lead). Note that passivation body 20 includes openings over pads 14 to allow for the reception of interconnect bodies 22 and adhesive bodies 18. Preferably, filler masses 24 (e.g. epoxy or the like) are disposed in the spaces between device 12 and substrate 10 to render enhanced mechanical integrity to the assembly thereof. In the first embodiment of the present invention, interconnect bodies 22 may be formed with an interconnect material containing conductive particles embedded in a solder matrix. An example of such a material is disclosed in U.S. patent application Ser. No. 10/970,165, assigned to the assignee of the present invention, the entire disclosure of which is incorporated by reference.

Referring now to FIG. 2, a package according to the present invention may be assembled on a circuit board 26 or the like by electrically and mechanically connecting each interconnect 22 to a respective conductive pad 28 on circuit board 26 through a conductive adhesive body 18 (e.g. solder, or a conductive polymer such as silver loaded epoxy). To render more mechanical stability, preferably thermally conductive adhesive 30 (such as a thermally conductive epoxy) can be applied to the back of device 12 and used to mechanically and thermally coupled device 12 to board 26. Note that in the event device 12 includes a back active electrode (e.g. a drain electrode) adhesive 30 may be replaced with an electrically conductive adhesive (e.g. solder or a conductive polymer) to connect the back electrode of device 12 to a corresponding conductive pad on board 26.

Referring next to FIG. 3, to further enhance the thermal characteristics of a package according to the present invention, a heat spreader 32 which may be formed from copper or a copper alloy or the like material may be thermally coupled to the back of silicon substrate 10 through a thermally conductive adhesive 34, such as a thermally conductive epoxy. Spreader 32 may be cup-shaped or can-shaped and may include legs which can be coupled through thermally conductive adhesive 36 (e.g. thermal epoxy or the like) to board 26 in order to allow for transfer of heat to board 26 and to render mechanical stability to the package. An example of a suitable heat spreader is the cup-shaped clip disclosed in U.S. Pat. No. 6,624,522, assigned to the assignee of the present application. Alternatively, as a further enhancement spreader 32 can be electrically connected to a back electrode of the die through silicon substrate 10 by a conductive adhesive and serve as an electrical connector connecting the back electrode to a corresponding pad on the circuit board.

Referring next to FIG. 4, a package according to the second embodiment includes conductive balls 38, for example, solder balls, instead to serve as leads or interconnects between pads 14 and a circuit board. In all other respects the second embodiment is identical to the first embodiment. Note that FIG. 4 shows a package according to the second embodiment assembled onto a circuit board 26 without adhesive 30. FIG. 5 illustrates the second embodiment of the present invention using adhesive 30.

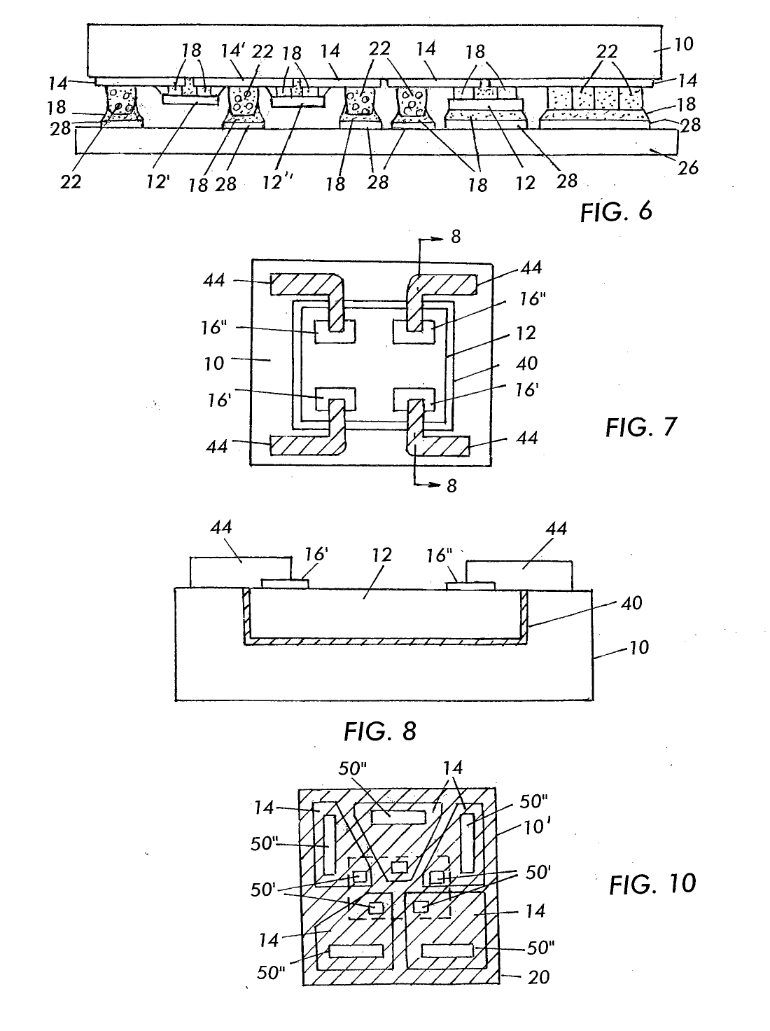

Referring to FIG. 6, a package according to the third embodiment may include more than one device 12, 12′, 12″ assembled onto a single silicon substrate 10. Thus, substrate 10 may be used for the assembly of multiple semiconductor devices and also passive components such as capacitors and the like to form a multichip integrated circuit. For example, device 12″ may be electrically connected to device 12′ through a common conductive pad 14′, whereby a circuit can be formed between the two devices.

Referring next to FIGS. 7 and 8, a substrate 10 in a package according to the fourth embodiment includes a recess 40 which receives semiconductor device 12. Note that device 12 may be mechanically coupled to the interior of recess 40 by an adhesive body 42 (e.g. thermal epoxy) whereby it is secured to silicon substrate 10. Note that device 12 is preferably thermally coupled to substrate 10 as well. Electrodes 16′, 16″ of device 12 are then redistributed to contact pads 44, that may be, for example, made from copper or the like. Contact pads 44 may be plated (e.g. through electroless or electroplating) onto electrodes 16′, 16″, whereby electrodes 16′, 16″ may be electrically and mechanically coupled to contact pads 44 without the use of a conductive adhesive or the like.

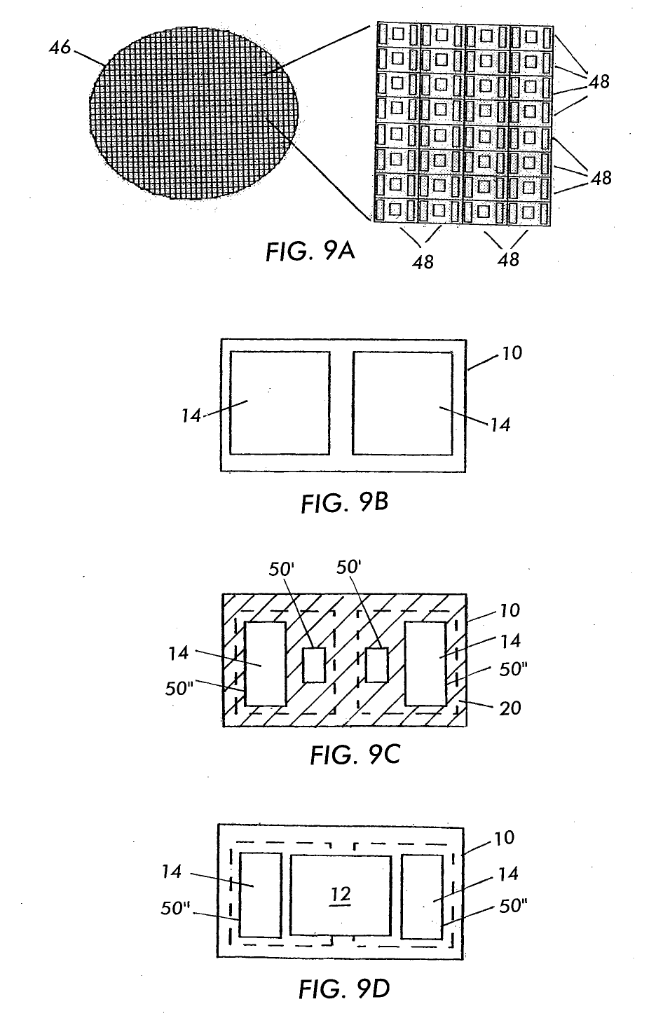

Referring next to FIGS. 9A-9D, a package according to the present invention (e.g. the first embodiment) is fabricated at wafer level, and then singulated into individual packages. Thus, as illustrated by FIG. 9A, a plurality of packages are fabricated on a silicon wafer 46, and then singulated by an appropriate cutting method. FIG. 9A illustrates a top plan of a wafer 46 which has been processed to obtain a plurality of packages 48 according to the first embodiment. Note that a portion of wafer 46 has been enlarged to show packages 48 prior to singulation.

Referring now specifically to FIGS. 9B-9D, each substrate 10 in a package according to the first embodiment of the present invention may include two adjacently disposed but spaced conductive pads 14. A passivation body 20 (illustrated in FIG. 9C by slanted lines) is then disposed on pads 14 and patterned to include openings 50′ each exposing a portion of a respective pad 14 for connection to electrodes 16′, 16″ of a semiconductor device, and openings 50″ each exposing a portion of a pad 14 for receiving interconnect 22. Thereafter, solder or the like conductive adhesive is deposited in openings 50′, and the electrodes 16′, 16″ of a semiconductor device 12 are attached to conductive pads 14 using the adhesive so deposited to obtain the assembly illustrated by FIG. 9D. Interconnect material can be deposited in openings 50″ before, or after the deposit of solder in openings 50′ to form interconnects 22, whereby a device according to the first embodiment may be obtained.

Referring now to FIG. 10, a silicon substrate 10′ as used in a package according to the present invention may include more than one conductive pad 14. Such a substrate may be used in combination with a semiconductor device having multiple electrodes such as an IC semiconductor device. Note that broken lines 52 identify the position of a semiconductor device to be assembled onto silicon substrate 10′ shown by FIG. 10.

Note that, according to one aspect of the present invention, in all embodiments disclosed herein the silicon substrate has a total area that is larger than the total area of the semiconductor device. Furthermore, note that the conductive pads on the substrate are much larger the electrodes of the semiconductor device, thus offering a larger area for external connection through for example, a lead (embodiments one, two and three) or directly (embodiment four). As a result the electrodes of the semiconductor device can be redistributed to a larger area for external connection.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed is:

1. A semiconductor package, comprising:
a silicon substrate having a total area;
a semiconductor device having a total area smaller than said total area of said substrate and at least one active electrode;
a conductive pad electrically and mechanically connected to said at least one active electrode and disposed on said silicon substrate, wherein said conductive pad includes an area for external connection that is larger than said at least one active electrode.

2. The semiconductor package of claim 1, wherein said conductive pad is disposed between said silicon substrate and said semiconductor die.

3. The semiconductor package of claim 2, further comprising an electrically conductive mass disposed on said area for external connection.

4. The semiconductor package of claim 3, wherein said electrically conductive mass includes conductive particles dispersed within a solder matrix.

5. The semiconductor package of claim 3, wherein said electrically conductive mass is a conductive ball.

6. The semiconductor package of claim 1, further comprising a heat spreader thermally coupled to said substrate.

7. The semiconductor package of claim 6, wherein said heat spreader is cup-shaped.

8. The semiconductor package of claim 1, further comprising another conductive pad electrically and mechanically coupled to at least another active electrode.

9. The semiconductor package of claim 1, wherein said semiconductor device is a power semiconductor device.

10. The semiconductor package of claim 1, wherein said semiconductor device is a power MOSFET and said at least one active electrode is the drain electrode of said MOSFET.

11. The semiconductor package of claim 1, wherein said at least one active electrode is electrically and mechanically connected to said conductive pad by a layer of conductive adhesive.

12. The semiconductor package of claim 11, further comprising a passivation body disposed around said conductive adhesive.

13. The semiconductor package of claim 12, wherein said passivation body defines said area for external connection.

14. The semiconductor package of claim 11, wherein said conductive adhesive is either solder or a conductive epoxy.

15. The semiconductor package of claim 1, wherein semiconductor device is disposed within a recess in said substrate and said conductive pad is disposed on a surface of said substrate that is parallel to a surface on which said at least one electrode is disposed.

16. The semiconductor package of claim 15, wherein said conductive pad is generally coplanar with said at least one electrode.

17. The semiconductor package of claim 15, wherein said semiconductor device is an IC.

18. The semiconductor package of claim 1, further comprising passive components disposed on said silicon substrate and operatively coupled to said semiconductor device.

19. The semiconductor package of claim 1, further comprising another semiconductor device disposed on said substrate and operative coupled to said semiconductor device to form an integrated circuit.
